(19) United States
(12) Patent Application Publication
(10) Pub. No.: US 2012/0199920 A1
(43) Pub. Date: Aug. 9, 2012

(54) STRUCTURED GLASS WAFER FOR PACKAGING A MICROELECTROMECHANICAL-SYSTEM (MEMS) WAFER

(76) Inventors: Zhuqing ZHANG, Corvallis, OR (US); Rodney L. Alley, Albany, OR (US)

(21) Appl. No.: 13/020,591

(22) Filed: Feb. 3, 2011

(51) Int. Cl. B32B 3/10; H01L 21/58; B32B 3/02; H01L 29/84

(52) U.S. Cl. 257/415; 438/51; 428/131; 428/66.6; 257/E29.324; 257/E21.505

(57) ABSTRACT

A structured glass wafer for packaging a microelectromechanical-system (MEMS) wafer. The structured glass wafer includes a sheet of glass, and an access hole. The sheet of glass has a first side and a second side, and is configured to provide a protective covering for MEMS devices. The access hole extends through the sheet of glass from the first side to the second side of the sheet of glass, and is configured to provide access to a group of electrical contacts of a group of MEMS devices. A packaged MEMS wafer including the structured glass wafer, and a method for fabricating a packaged MEMS wafer are also provided.

### TECHNICAL FIELD

Examples of the present technology relate generally to microelectromechanical (MEMS) devices.

### BACKGROUND

Research and development of microelectromechanical (MEMS) devices is a rapidly advancing technological field. MEMS devices offer potential applications in a whole variety of disciplines ranging from medicine to geophysical prospecting. Scientists and engineers engaged in the research and development of MEMS devices are actively pursuing new applications. However, the complex fabrication techniques used to make MEMS devices provide a number of technical challenges. In particular, the cost of fabricating MEMS devices can present a barrier to the implementation of MEMS devices for certain new applications.

Thus, scientists and engineers engaged in the research and development of MEMS devices are motivated to reduce the cost of fabrication techniques used to make MEMS devices in the hope of expanding the application of MEMS devices in potential new markets.

### DESCRIPTION OF THE DRAWINGS

The accompanying drawings, which are incorporated in and form a part of this specification, illustrate examples of the technology and, together with the description, serve to explain the examples of the technology:

FIG. 1A is a plan view of a front side of a structured glass wafer, used as a cover wafer, or “C-wafer,” for packaging a microelectromechanical-system (MEMS) wafer, which includes a plurality of access holes configured to provide access to a plurality of electrical contacts of the MEMS wafer, in accordance with examples of the present technology.

FIG. 1B is a plan view of a back side of the structured glass wafer of FIG. 1 that includes a plurality of cavities configured to accommodate a plurality of movable portions of respective MEMS devices of the MEMS wafer, in accordance with examples of the present technology.

FIG. 1C is another plan view of the back side of the structured glass wafer of FIG. 1 that details the arrangement of both the plurality of cavities and the plurality of access holes, which extend through a sheet of glass of which the structured glass wafer is formed, in accordance with examples of the present technology.

FIG. 2A is a plan view of a front side of a first wafer of which a MEMS wafer is formed, an electrical wafer, or “E-wafer,” showing a plurality of electrical contacts of a plurality of MEMS devices, in accordance with examples of the present technology.

FIG. 2B is a plan view of a front side of a second wafer of which the MEMS wafer is formed, a mechanical wafer, or “M-wafer,” showing a plurality of cavities configured to allow motion of movable portions of the plurality of MEMS devices, in accordance with examples of the present technology.

FIG. 2C is a plan view of a front side of the MEMS wafer that includes the E-wafer of FIG. 2A bonded to the M-wafer of FIG. 2B, showing an arrangement of the plurality of MEMS devices, in accordance with examples of the present technology.

FIG. 2D is another plan view of the front side of the MEMS wafer that includes the E-wafer and the M-wafer of FIGS. 2A and 2B, respectively, showing an arrangement of the plurality of cavities configured to allow motion of movable portions within the plurality of MEMS devices, in accordance with examples of the present technology.

FIG. 2E is another plan view of the front side of the MEMS wafer that includes the E-wafer and the M-wafer of FIGS. 2A and 2B, showing an arrangement of the plurality of cavities configured to allow motion of movable portions, and of a plurality of through holes configured to allow access to the plurality of electrical contacts within the plurality of MEMS devices, in accordance with examples of the present technology.

FIG. 3A is a plan view of a front side of a packaged MEMS wafer that includes the C-wafer, the E-wafer and the M-wafer of respective FIGS. 1A-2E, showing an arrangement of the plurality of access holes in the C-wafer configured to provide access to the plurality of electrical contacts of the E-wafer with respect to a plurality of packaged MEMS devices, in accordance with examples of the present technology.

FIG. 3B is another plan view of the front side of the packaged MEMS wafer of FIG. 3A, after dicing the packaged MEMS wafer into a plurality of discrete packaged MEMS devices, showing an arrangement of a plurality of covering lids of the C-wafer configured to cover the plurality of discrete packaged MEMS devices, in accordance with examples of the present technology.

FIG. 4A is a cross-sectional elevation view of a MEMS device of FIG. 2C along the line 4A-4A of FIG. 2C, showing the MEMS device after first trenches are etched on the back side of the M-wafer, and after bonding the E-wafer to the M-wafer to produce the MEMS wafer, in accordance with examples of the present technology.

FIG. 4B is another cross-sectional elevation view of the MEMS device of FIG. 4A along the line 4B-4B of FIG. 2D, showing the MEMS device after second trenches are etched on the front side of the M-wafer, and after the plurality of cavities are produced in the M-wafer to allow motion of movable portions within the plurality of MEMS devices, in accordance with examples of the present technology.

FIG. 4C is another cross-sectional elevation view of the MEMS device of FIG. 4A along the line 4C-4C of FIG. 2E, showing the MEMS device after a plurality of block portions of the M-wafer are removed to expose the plurality of electrical contacts on the E-wafer of the plurality of MEMS devices of the MEMS wafer, in accordance with examples of the present technology.

FIG. 4D is another cross-sectional elevation view of the discrete packaged MEMS device of FIG. 3B along the line 4D-4D of FIG. 3B, showing the packaged MEMS device after bonding the structured glass wafer of FIG. 1C to the MEMS wafer of FIG. 2E to provide a packaged MEMS wafer, and after dicing the packaged MEMS wafer of FIG. 3A to produce a plurality of discrete packaged MEMS devices, in accordance with examples of the present technology.

FIG. 4E is another cross-sectional elevation view of a discrete packaged MEMS device similar to that of FIG. 3B, showing the packaged MEMS device after bonding a structured glass wafer similar to that of FIG. 1C, but without cavities on the second side, to the MEMS wafer of FIG. 2E to provide a packaged MEMS wafer, and after dicing the packaged MEMS wafer to produce a plurality of discrete packaged MEMS devices, in accordance with examples of the present technology.

FIG. 4F is another cross-sectional elevation view of a discrete packaged MEMS device similar to that of FIG. 3B, showing the packaged MEMS device after bonding the structured glass wafer of FIG. 1C to a MEMS wafer similar to that of FIG. 2E, but with a movable portion having an additional mass, to provide a packaged MEMS wafer, and after dicing the packaged MEMS wafer to produce a plurality of discrete packaged MEMS devices, in accordance with examples of the present technology.

FIG. 5A is a flowchart of a method for fabricating a packaged MEMS wafer, in accordance with examples of the present technology.

FIG. 5B is a flowchart of further operations that may be employed in the method for fabricating the packaged MEMS wafer, in accordance with examples of the present technology.

The drawings referred to in this description should not be understood as being drawn to scale except if specifically noted.

### DESCRIPTION OF EXAMPLES

Reference will now be made in detail to the alternative examples of the present technology. While the technology will be described in conjunction with the alternative examples, it will be understood that they are not intended to limit the technology to these examples. On the contrary, the technology is intended to cover alternatives, modifications and equivalents, which may be included within the spirit and scope of the technology as defined by the appended claims.

Furthermore, in the following description of examples of the present technology, numerous specific details are set forth in order to provide a thorough understanding of the present technology. However, it should be noted that examples of the present technology may be practiced without these specific details. In other instances, well known methods, procedures, and components have not been described in detail as not to unnecessarily obscure examples of the present technology. Throughout the drawings, like components are denoted by like reference numerals, and repetitive descriptions are omitted for clarity of explanation if not necessary.

Examples of the present technology include a structured glass wafer for packaging a microelectromechanical-system (MEMS) wafer. The structured glass wafer includes a sheet of glass, and an access hole. As used herein, the term of art, “cover wafer,” and/or “C-wafer,” may be used to refer to the structured glass wafer. The sheet of glass has a first side and a second side opposite the first side, and is configured to provide a protective covering for MEMS devices. The access hole extends through the sheet of glass from the first side to the second side of the sheet of glass, and is configured to provide access to a group of electrical contacts of a group of MEMS devices. The structured glass wafer may also include a plurality of cavities. The plurality of cavities is formed in the second side of the sheet of glass, do not extend completely through the sheet of glass, and is configured to accommodate respective MEMS devices. Other examples of the present technology also include a packaged MEMS wafer including the structured glass wafer, and a method for fabricating the packaged MEMS wafer.

As used herein, the term of art, “electrical contact,” refers to any of the following, without limitation thereto: an electrical contact pad, as may be used to test, or probe, the electrical functionality of a MEMS device; and, an electrical bonding pad, as may be used to provide electrical continuity between an electrical component in the MEMS device and external electrical components, as in forming an electrical circuit including the electrical component in the MEMS device and the external electrical components, through an ultrasonic, thermal compression, or other type of wire bond. Moreover, as known from the art of microelectronic fabrication technology, the term of art, “pad,” refers to the thin-film, or thick-film, landing structure, which may also be referred to as a “land,” with which an electrical probe, a wire, and or an electrical interconnect may electrically couple, without limitation thereto.

As is known in the art, a silicon cover wafer rather than a glass cover wafer is typically used to cover a MEMS wafer. The silicon cover wafer employs a costly and complicated bonding process to cover the MEMS wafer. Thus, in accordance with examples of the present technology, the use of a glass cover wafer may result in higher throughput and lower assembly cost for the MEMS wafer, because the bonding process for the silicon wafer is eliminated and the bonding process for glass cover wafer is less costly. Moreover, examples of the present technology provide an access-hole morphology that is designed to provide access to a plurality of electrical contacts of a plurality of underlying MEMS devices, which speeds wafer-level probing of electrical contacts of encapsulated MEMS devices for wafer-level testing, which further reduces cost. However, a trade-off exists with respect to the use of a glass cover wafer that makes the usual process of sawing through the cover wafer to expose the electrical contacts very time consuming, and therefore costly. Examples of the present technology overcome this trade-off by prefabricating the plurality of cavities and access holes in the glass cover-wafer. In accordance with examples of the present technology, prefabricating the plurality of access holes in the glass cover-wafer avoids the costly glass sawing process. Examples of the present technology including the glass cover wafer can be readily identified by a conspicuous structure of elongated access holes, so called “streets,” for accessing pluralities of electrical contacts of pluralities of MEMS devices.

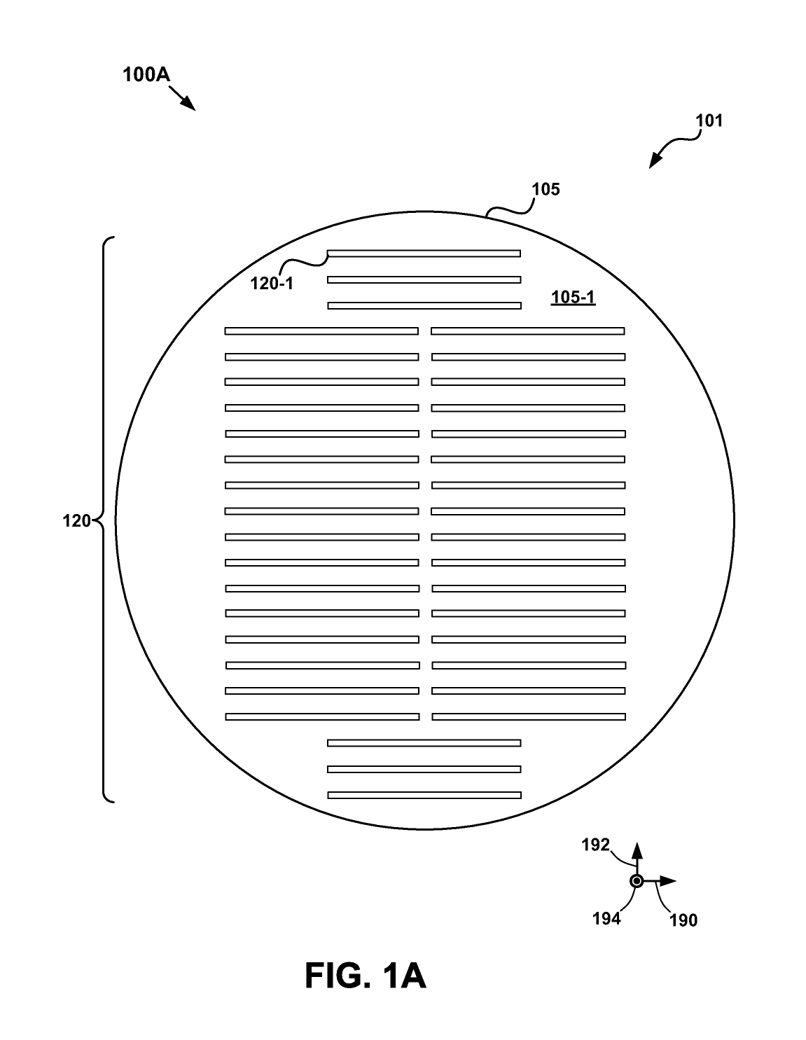

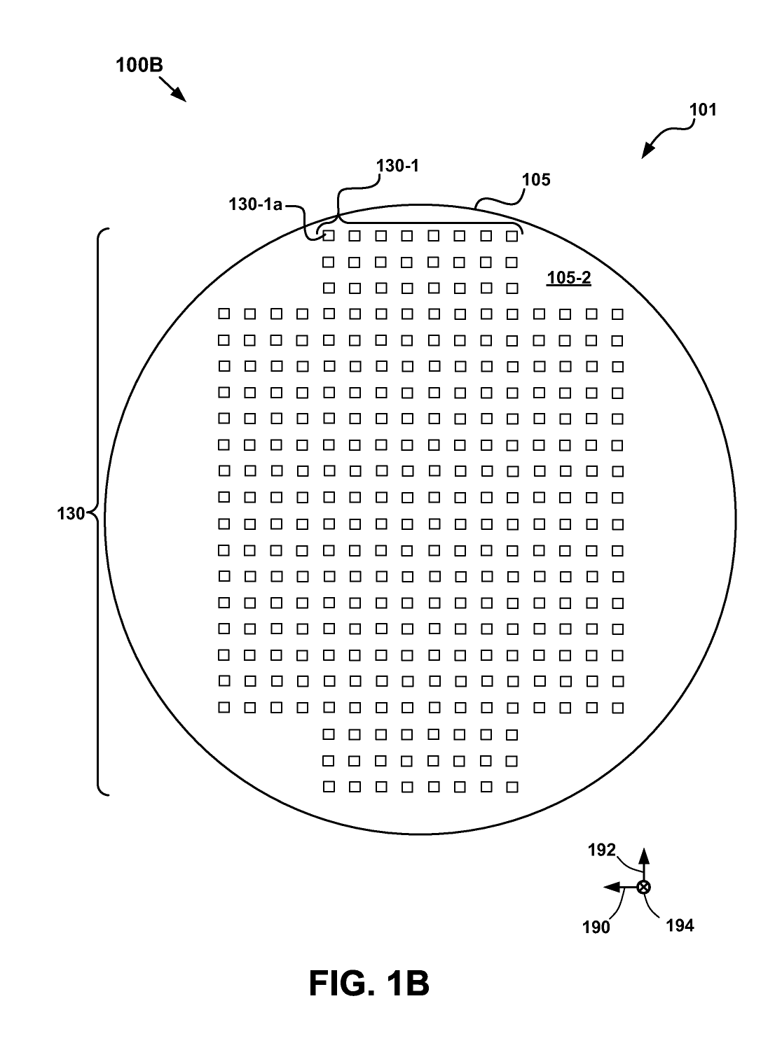

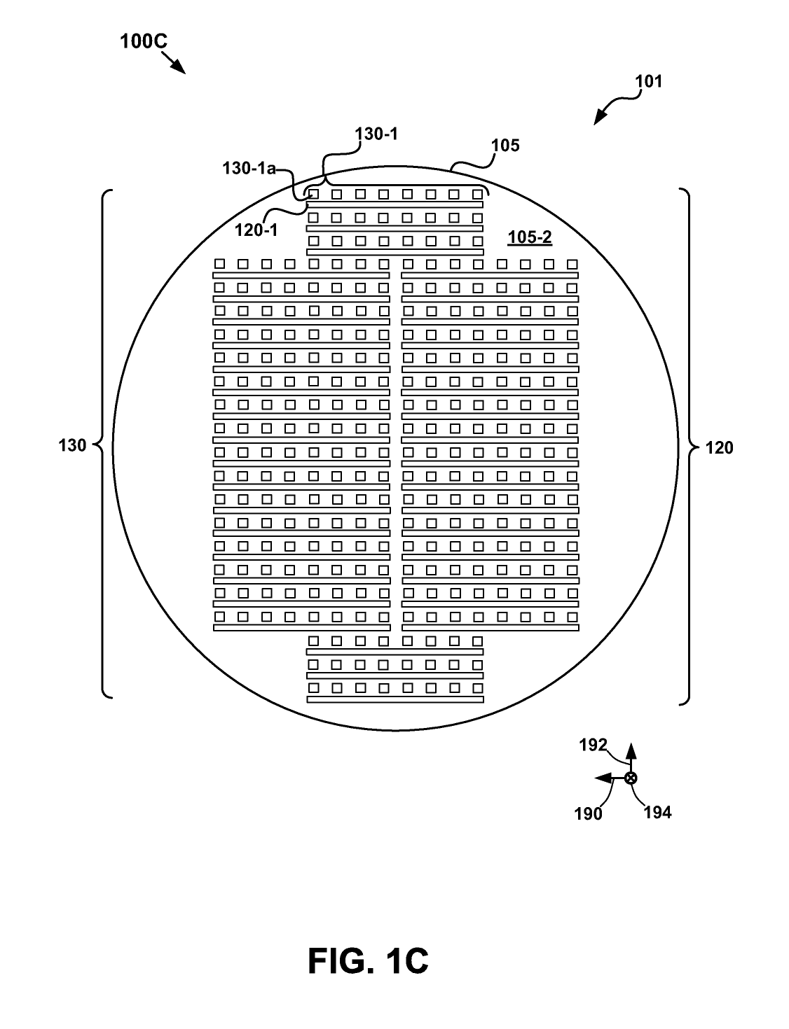

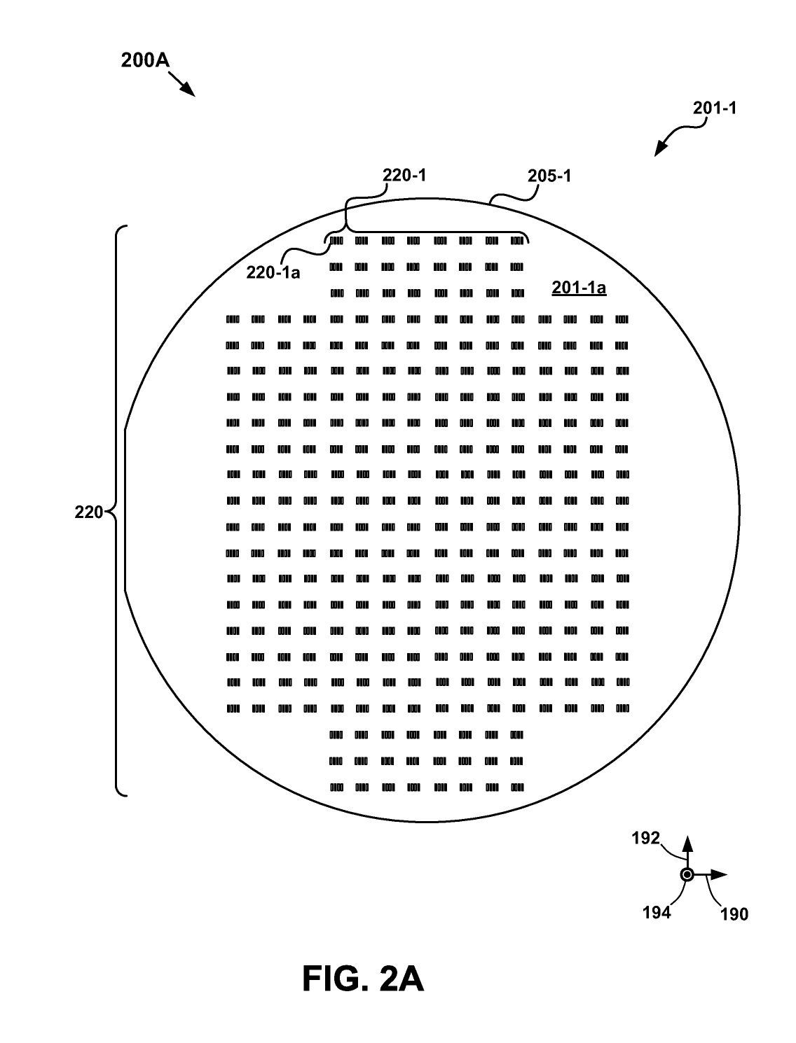

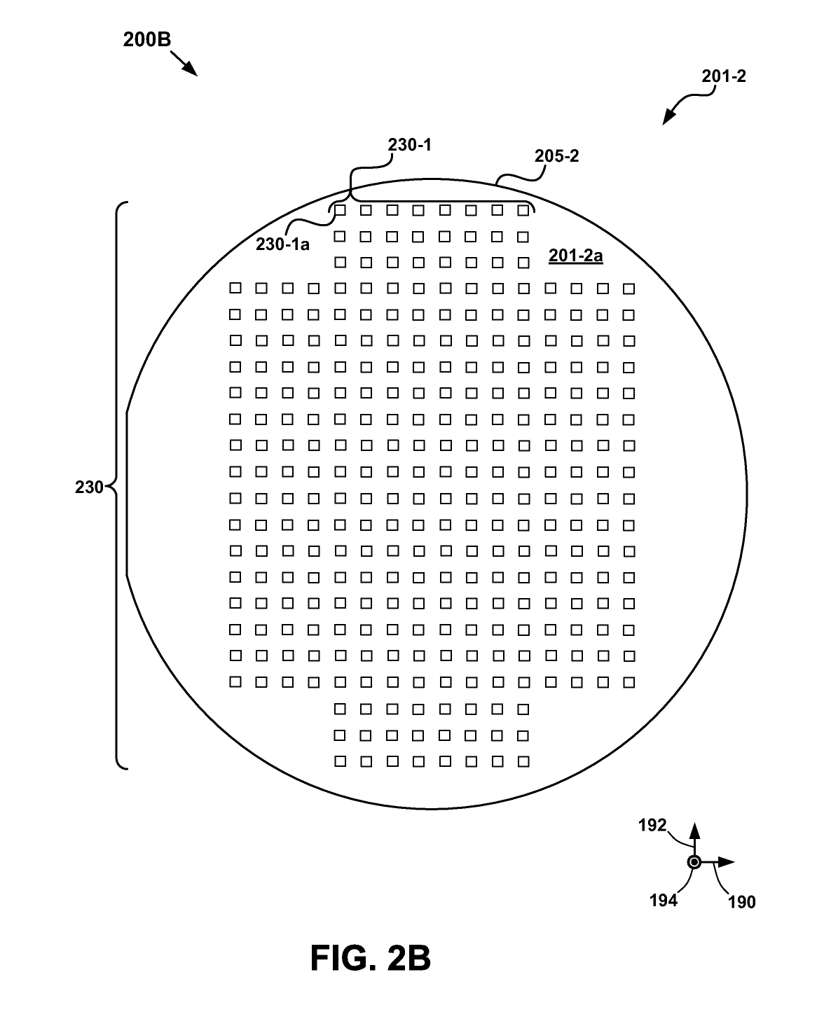

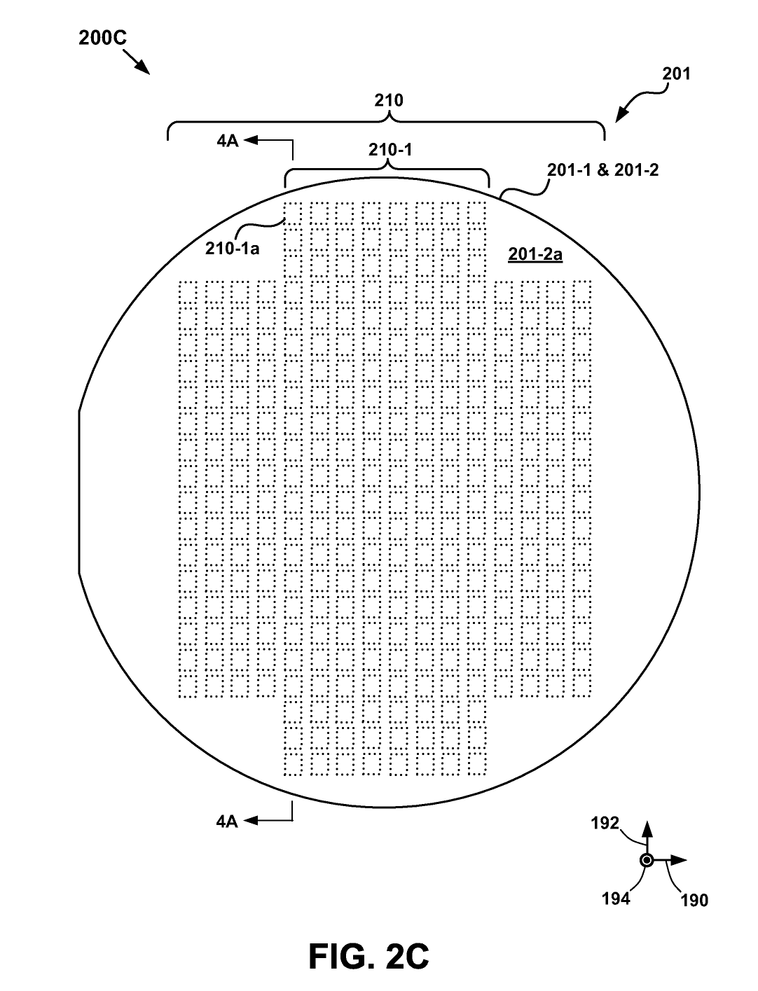

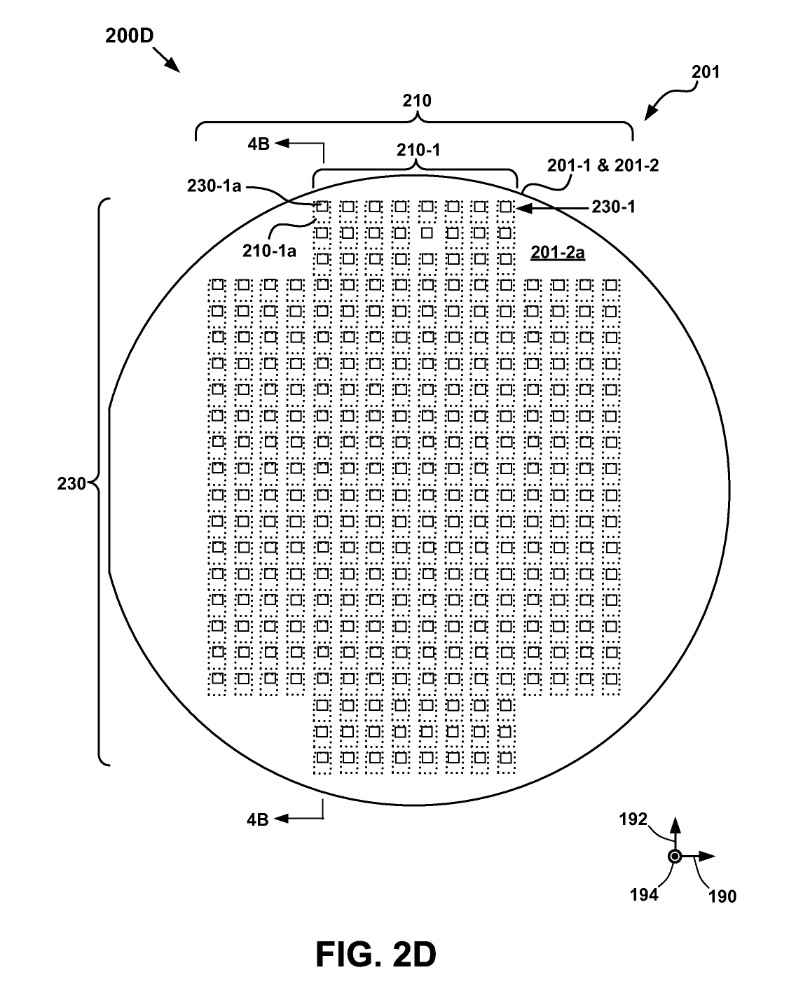

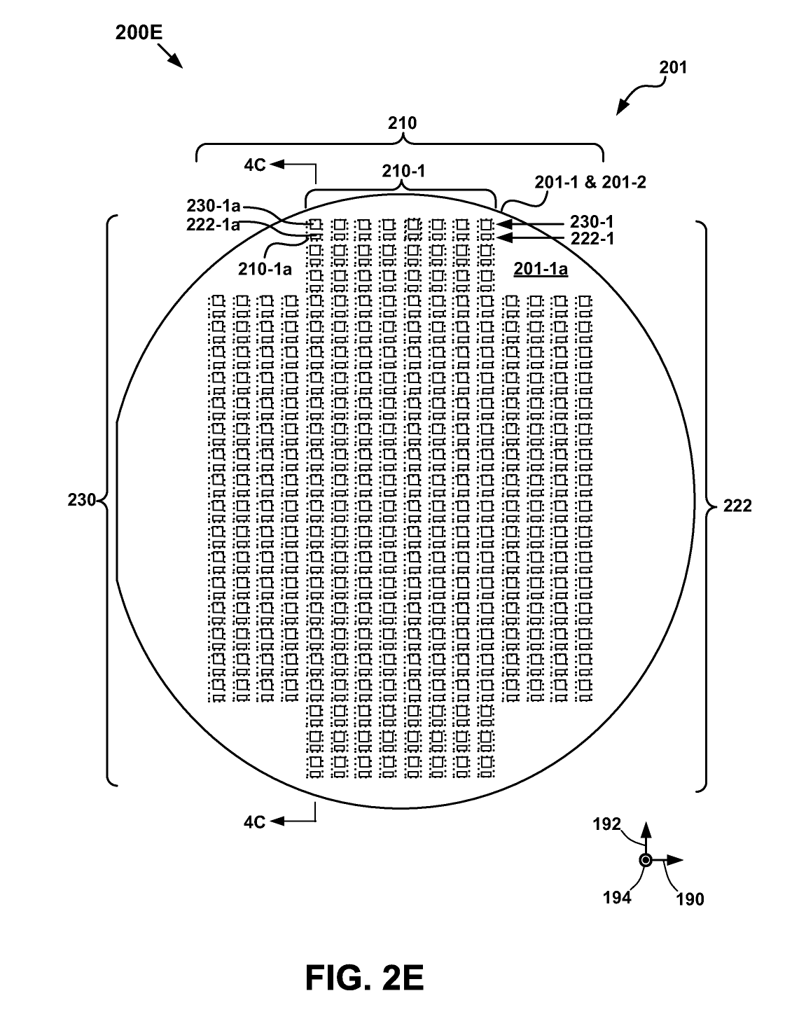

With reference now to FIG. 1A, in accordance with examples of the present technology, a plan view 100A is shown of a first side 105-1, which is the front side, of a structured glass wafer 101 for packaging a MEMS wafer 201 (see FIGS. 2C-2E). The structured glass wafer 101, which is the cover wafer, referred to as a C-wafer, includes a plurality 120 of access holes, for example, access hole 120-1, configured to provide access to a plurality 220 (see FIG. 2A) of electrical contacts of a plurality 210 (see FIGS. 2C-2E) of MEMS devices. The structured glass wafer 101 includes a sheet of glass 105 having a first side 105-1 and a second side 105-2 opposite the first side 105-1 and an access hole, for example, access hole 120-1. The sheet of glass 105 is configured to provide a protective covering for MEMS devices of the MEMS wafer 201. The access hole 120-1 extends through the sheet of glass 105 from the first side 105-1 to the second side 105-2 of the sheet of glass 105. The access hole 120-1 is configured to provide access to a group 220-1 of electrical contacts of a group 210-1 of MEMS devices.

With further reference to FIG. 1A, in accordance with examples of the present technology, a triad of vectors 190, 192 and 194 is provided in FIG. 1A, to ease description. The triad of vectors 190, 192 and 194 is right handed; thus, the vectors 190, 192 and 194 may be mutually orthogonal unit vectors such that the vector product of vector 190 with vector 192 produces vector 194. The triad of vectors 190, 192 and 194 provides a reference for determining the relationship of other drawings for examples of the present technology with respect to FIG. 1A, as well as other drawings. As the MEMS wafer is essentially a layered structure, the terms of art “upper,” or “above,” as used herein, refer to a side of a layer of the MEMS wafer that is normal to vector 194 and faces the direction in which the arrow head of vector 194 points. As used herein, the terms of art “lower,” or “below,” refer to a side of a layer of the MEMS wafer that is normal to vector 194 and faces the direction opposite to the direction in which the arrow head of vector 194 points. As described herein, the MEMS wafer includes: a first wafer, which is defined as the lower wafer, which is an electrical wafer, referred to by the term of art, “E-wafer;” a second wafer, which is a middle wafer, which is a mechanical wafer, referred to by the term of art, “M-wafer;” and the structured glass wafer 101, which is defined as the upper wafer, which is a cover wafer, referred to by the term of art, “C-wafer.” As is known in the art, these terms of art are relative, and conventional, with respect to a structure, such as the MEMS wafer, which is fabricated with a process that essentially lays successive layers down over a substrate, or wafers upon one another, and do not necessarily imply any specific orientation of the MEMS wafer, or component parts of the MEMS wafer, with respect to an external reference frame, for example, the surface of the Earth. Thus, the term of art, “vertical,” as used herein refers to a sequence of layers, or wafers, from the lower wafer to the upper wafer of the MEMS wafer, or vice versa. Thus, the vertical direction is the direction of the vector 194.

Similarly, with further reference to FIG. 1A, the term of art “front” refers to a side of a wafer that is normal to vector 194 and faces the direction in which the arrow head of vector 194 points. The term of art “back” refers to a side of a wafer that is normal to vector 194 and faces in the direction opposite to the direction in which the arrow head of vector 194 points. Likewise, the term of art “right” refers to a side of a wafer that lies towards the right side of a drawing, for example, in FIG. 1A the arrow head of vector 190 points to the right. The term of art “left” refers to a side of a wafer that lies towards the left side of a drawing, for example, in FIG. 1A the arrow head of vector 190 points opposite to the left. Likewise, the term of art “top” refers to a side of a wafer that lies towards the top side of a drawing, for example, in FIG. 1A the arrow head of vector 192 points towards the top of the wafer. The term of art “bottom” refers to a side of a wafer that lies towards the bottom side of drawing, for example, in FIG. 1A the arrow head of vector 192 points opposite to the bottom of the wafer. Similarly, as is known in the art, these terms of art are relative, and conventional, with respect to a structure, such as the MEMS wafer, which is fabricated with a plurality of wafers, and do not necessarily imply any specific orientation of the MEMS wafer, or component parts of the MEMS wafer, with respect to an external reference frame, for example, the surface of the Earth. Thus, the term of art, “lateral,” as used herein refers to a sequence of structures from top to bottom, from bottom to top, or alternatively, from left to right, or from right to left, in plan view drawings of wafers.

With further reference to FIG. 1A, in accordance with examples of the present technology, the structured glass wafer 101 may further include a plurality 120 of access holes such that the plurality 120 of access holes is prefabricated in the sheet of glass 105 prior to bonding the structured glass wafer 101 to the MEMS wafer 201 shown in FIGS. 2C-2E. The plurality 120 of access holes may also include a plurality of open streets in the sheet of glass 105. By way of example, the sheet of glass 105 may have about a circular shape, as shown in FIG. 1A, without limitation thereto. A sheet of glass 105 that has the circular shape may have a diameter of greater than or equal to about 20 millimeters (mm).

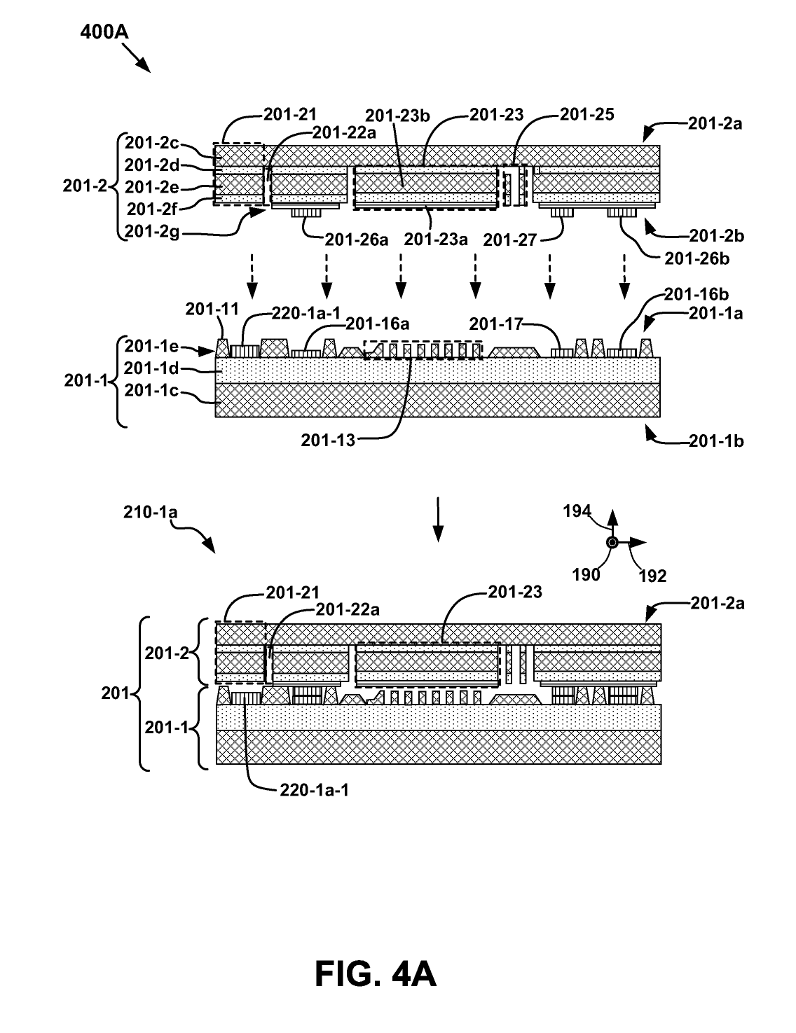

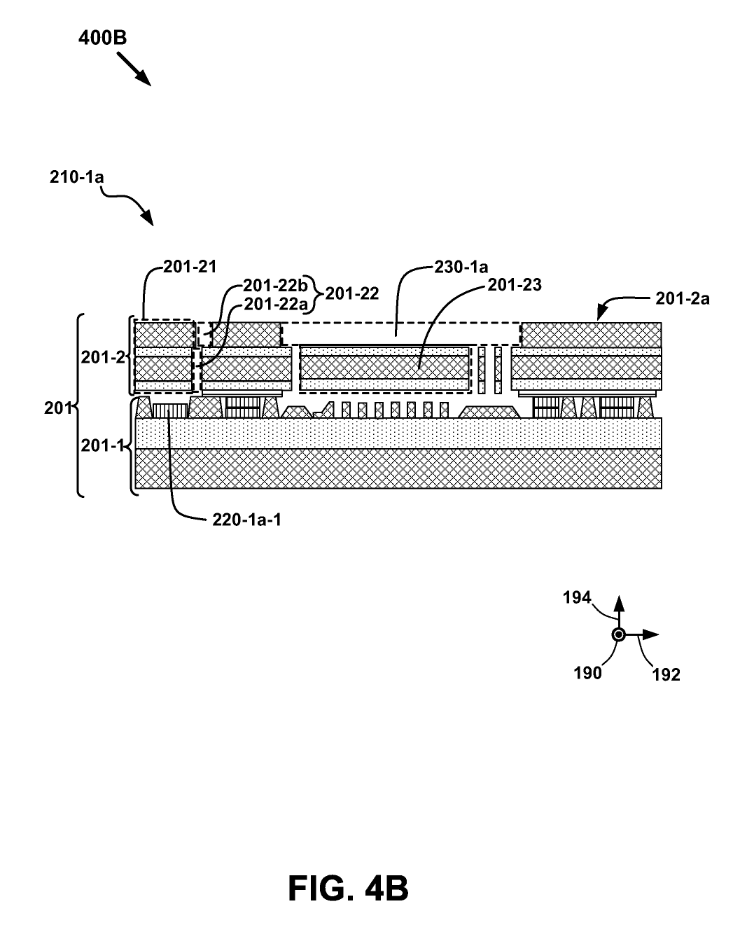

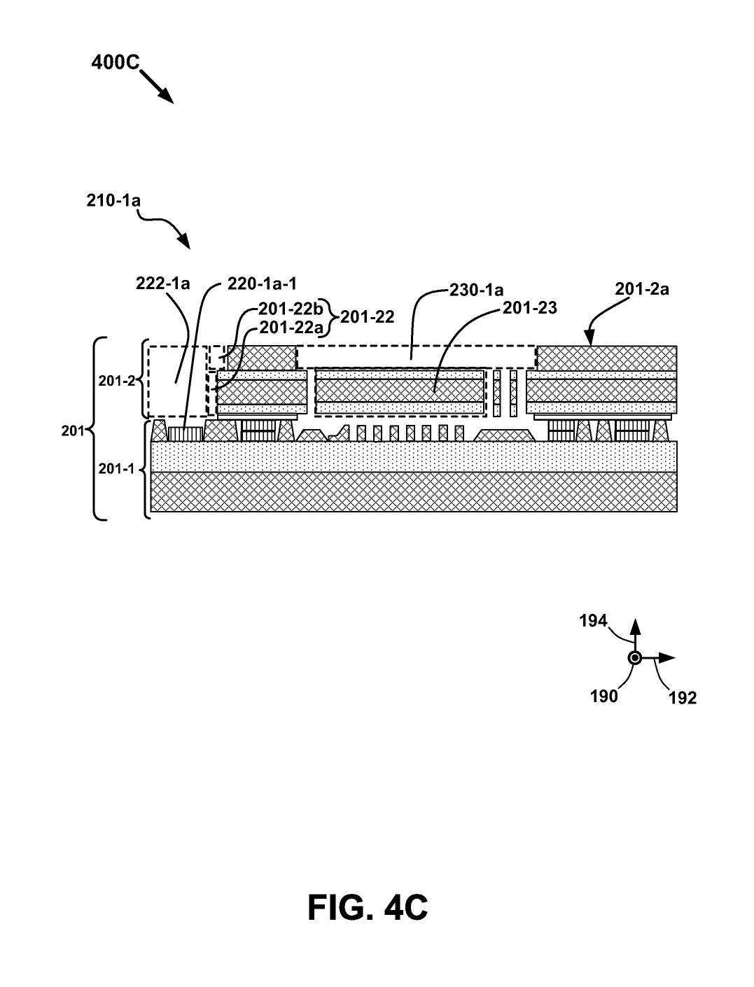

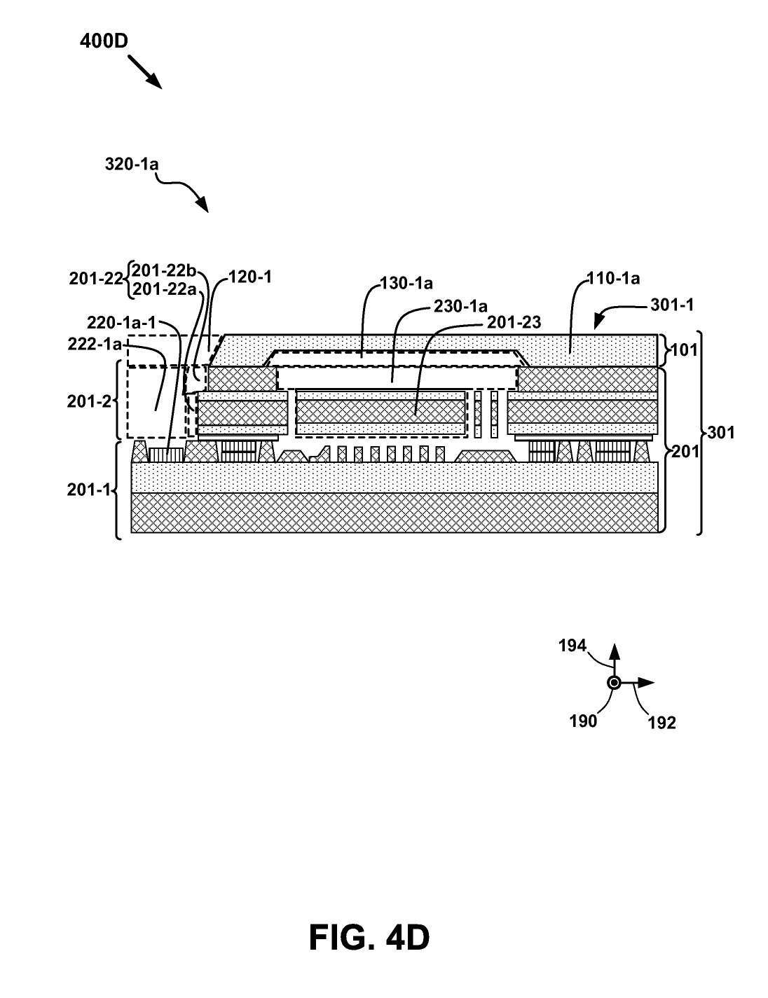

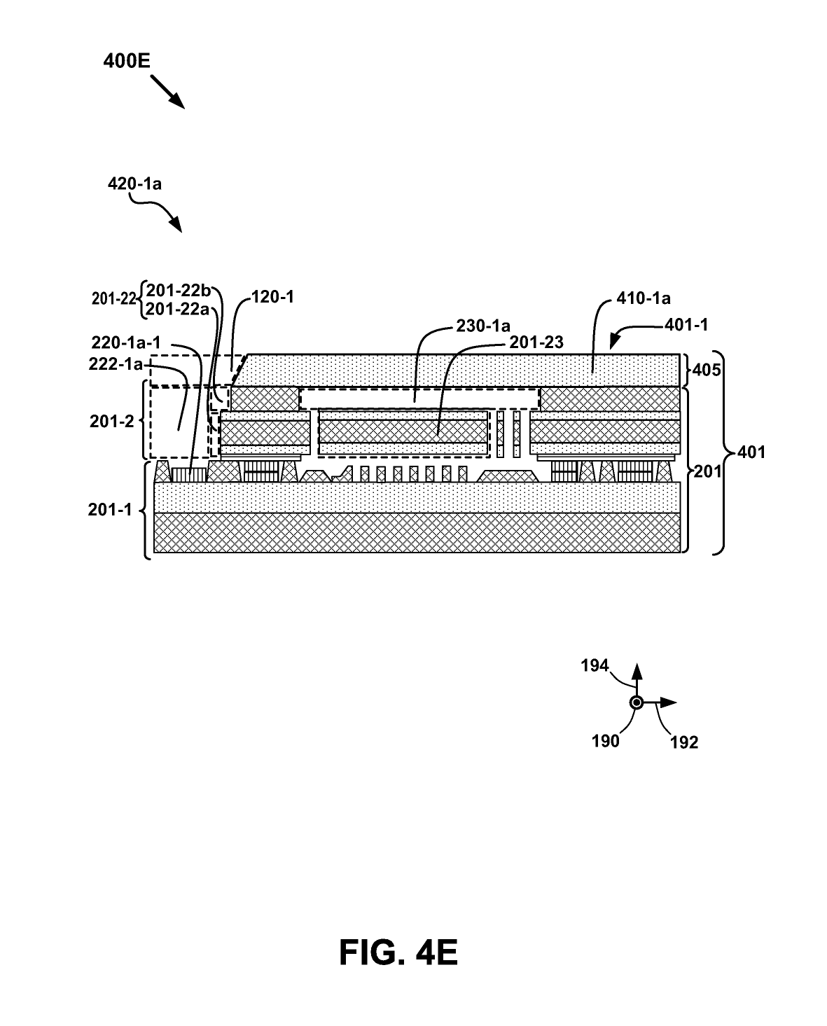

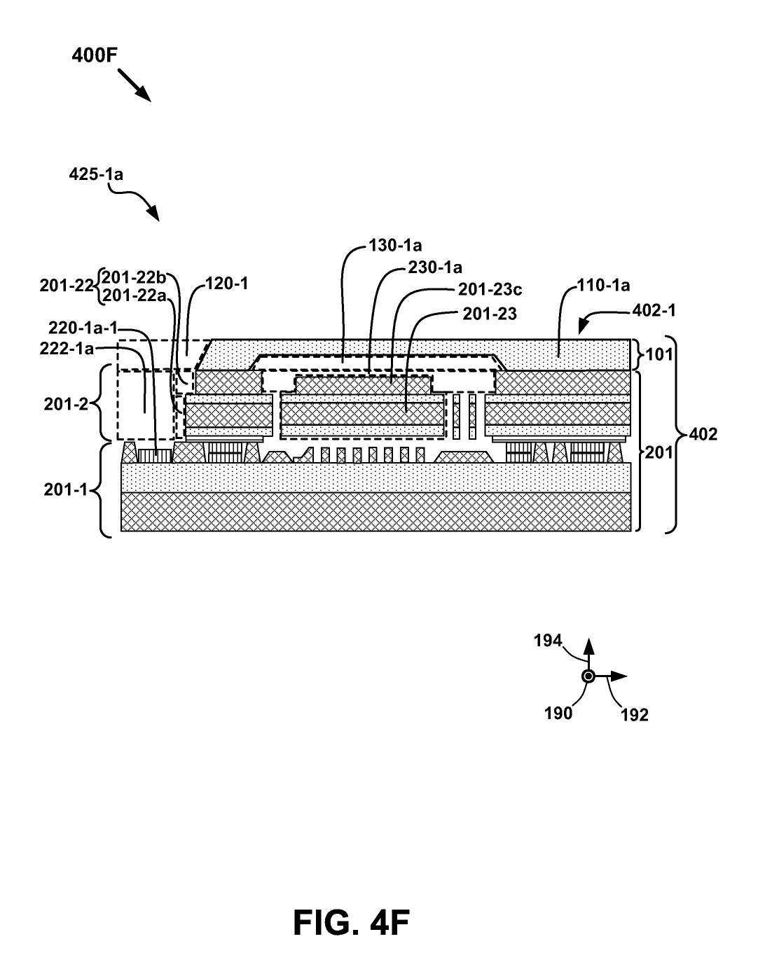

With reference now to FIG. 1B, in accordance with examples of the present technology, a plan view 100B is shown of a second side 105-2, which is the back side, of the structured glass wafer 101 of FIG. 1A. The triad of vectors 190, 192 and 194 indicates the orientation of plan view 100B relative to the plan view 100A of FIG. 1A. The structured glass wafer 101 may also include a plurality 130 of cavities. The plurality 130 of cavities includes a group 130-1 of cavities, of which cavity 130-1a is an example. As used herein, the term of art, “group,” refers to a lesser number of structures than the set of structures to which the term of art plurality refers. As shown in FIG. 1B, the group 130-1 of cavities includes the top row of cavities of the plurality 130 of cavities. The cavities are formed in the second side 105-2 of the sheet of glass 105. The cavities do not extend completely through the sheet of glass 105. The cavities are configured to accommodate a plurality of movable portions of respective MEMS devices of the MEMS wafer 201 (see FIGS. 2C-2E and 4A-4C). The plurality 130 of cavities may be prefabricated in the sheet of glass 105 prior to bonding the structured glass wafer 101 to a MEMS wafer 201. As suggested by FIG. 1A, the plurality 130 of cavities may be prefabricated in the sheet of glass 105 prior to fabrication of the plurality 120 of access holes in the sheet of glass 105. Other details of the fabrication process of the structured glass wafer 101 are next described.

With reference now to FIG. 1C, in accordance with examples of the present technology, another plan view 100C is shown of the second side 105-2, the back side, of the structured glass wafer 101 of FIG. 1. The triad of vectors 190, 192 and 194 indicates the orientation of plan view 100C relative to the plan views 100A and 100B of FIGS. 1A and 1B. FIG. 2C details the arrangement of both the plurality 130 of cavities and the plurality 120 of access holes, which extend through a sheet of glass 105, of which the structured glass wafer 101 is formed, from the first side 105-1 to the second side 105-2 of the sheet of glass 105. A variety of processes may be used to fabricate the structured glass wafer 101, as follows, by way of example without limitation thereto: molding of the structured glass wafer 101 with the plurality 130 of cavities and the plurality 120 of access holes molded into the form of the structured glass wafer 101; milling, for example, ion milling, the plurality 130 of cavities and the plurality 120 of access holes into a prefabricated blank glass wafer; and, mechanically machining, for example, slurry grinding, the plurality 130 of cavities and the plurality 120 of access holes into a prefabricated blank glass wafer.

With reference now to FIG. 2A, in accordance with examples of the present technology, a plan view 200A is shown of a first side 201-1a, which is the front side, of a first wafer 201-1 of which a MEMS wafer 201 (see FIGS. 2C-2E) is formed. As used herein the term of art, “electrical wafer,” and/or “E-wafer,” refers to the first wafer 201-1 of the MEMS wafer 201. The triad of vectors 190, 192 and 194 indicates the orientation of plan view 200A relative to the plan views 100A-100C of FIGS. 1A-1C. FIG. 2A shows a plurality 220 of electrical contacts of a plurality 210 (see FIG. 2C) of MEMS devices. The plurality 220 of electrical contacts includes the group 220-1 of electrical contacts, of which electrical contacts 220-1a are an example. By way of example, each MEMS device may include more than one electrical contact, without limitation thereto. As shown in FIG. 2A, the group 220-1 of electrical contacts includes the top row of electrical contacts of the plurality 220 of electrical contacts. The plurality 220 electrical contacts is laid out in an orderly array of rows and columns, as is used in a step-and-repeat process for batch processing of devices of a wafer. Thus, the plurality 220 of electrical contacts of the first side 201-1a, front side, of the electrical wafer, E-wafer, shown in FIG. 2A, is laid out for alignment with the plurality 120 of access holes of the cover wafer, C-wafer, shown in FIG. 1A. By way of example, the E-wafer may be a silicon wafer, without limitation thereto. Thus, a wafer flat characteristic of a silicon wafer, which may be used for alignment of the E.-wafer, is shown on the left side of the E-wafer of FIG. 2A.

With reference now to FIG. 2B, in accordance with examples of the present technology, a plan view 200B is shown of a first side 201-2a, which is the front side, of a second wafer 201-2 of which the MEMS wafer 201 (see FIGS. 2C-2E) is formed. As used herein the term of art, “mechanical wafer,” and/or “M-wafer,” refers to the second wafer 201-2 of the MEMS wafer 201. The triad of vectors 190, 192 and 194 indicates the orientation of plan view 200B relative to the plan views 100A-200A of FIGS. 1A-2A. FIG. 2B shows a plurality 230 of cavities, which are configured to allow motion of movable portions of the plurality 210 (see FIG. 2C) of MEMS devices. The plurality 230 of cavities includes a group 230-1 of cavities, of which cavity 230-1a is an example. As shown in FIG. 2B, the group 230-1 of cavities includes the top row of cavities of the plurality 230 of cavities. The plurality 230 of cavities is also laid out in an orderly array of rows and columns. Thus, the plurality 230 of cavities of the first side 201-2a, front side, of the mechanical wafer, M-wafer, shown in FIG. 2B, is laid out, after turning over the structured glass wafer 101 from the orientation shown in FIGS. 1B and 1C, for alignment with the plurality 130 of cavities on the second side 105-2, back side, of the cover wafer, C-wafer, shown in FIGS. 1B and 1C. By way of example, the M-wafer may also be a silicon wafer, without limitation thereto. Thus, a wafer flat characteristic of a silicon wafer, which may be used for alignment of the M-wafer, is shown on the left side of the M-wafer of FIG. 2B.

With reference now to FIG. 2C, in accordance with examples of the present technology, a plan view 200C is shown of a first side 201-2a, which is the front side, of the MEMS wafer 201 that includes the first wafer 201-1, E-wafer, of FIG. 2A bonded to the second wafer 201-2, M-wafer, of FIG. 2B. The triad of vectors 190, 192 and 194 indicates the orientation of plan view 200C relative to the plan views 100A-200B of FIGS. 1A-2B. FIG. 2C shows an arrangement of the plurality 210 of MEMS devices, prior to etching the plurality 230 of cavities (see FIG. 2D) and producing a plurality 222 of through holes (see FIG. 2E) in the second wafer 201-2, M-wafer, of the MEMS wafer 201. The plurality 210 of MEMS devices includes the group 210-1 of MEMS devices, of which MEMS device 210-1a is an example. As shown in FIG. 2C, the group 210-1 of MEMS devices includes the top row of MEMS devices of the plurality 210 of MEMS devices. The plurality 210 of MEMS devices is also laid out in an orderly array of rows and columns. The MEMS wafer 201 includes both the first wafer 201-1, E-wafer, and the second wafer 201-2, M-wafer, which are aligned with one another for bonding to produce the MEMS wafer 201. The first wafer 201-1, E-wafer, has a plurality of electrical components of the respective MEMS devices of the MEMS wafer 201. The second wafer 201-2, M-wafer, has a plurality of movable portions of respective MEMS devices of the MEMS wafer 201. The wafer flats of both the M-wafer and the E-wafer, shown on the left side of the MEMS wafer 201 of FIG. 2C, may aid in alignment of the plurality of electrical components of the first wafer 201-1, E-wafer, with the plurality of movable portions of the second wafer 201-2, M-wafer, before bonding the M-wafer to the E-wafer to form the MEMS wafer 201. Line 4A-4A indicates the location of a cross-section through the MEMS wafer 201, which is useful for describing both the bonding operation of the first wafer 201-1, E-wafer, to the second wafer 201-2, M-wafer, to form the MEMS wafer 201, and the arrangement of the electrical components of the first wafer 201-1, E-wafer, with the movable portions of the second wafer 201-2, M-wafer, in the MEMS device 210-1a, which is subsequently described in discussion of FIG. 4A.

With reference now to FIG. 2D, in accordance with examples of the present technology, another plan view 200D is shown of the first side 201-2a, which is the front side, of the MEMS wafer 201 that includes the E-wafer, which is first wafer 201-1, and the M-wafer, which is second wafer 201-2, of FIGS. 2A and 2B, respectively. The triad of vectors 190, 192 and 194 indicates the orientation of plan view 200D relative to the plan views 100A-200C of FIGS. 1A-2C. FIG. 2D shows an arrangement of the plurality 230 of cavities in the MEMS wafer 201, after etching the plurality 230 of cavities in the second wafer 201-2 of the MEMS wafer 201. Similar to FIG. 2C, the plurality 210 of MEMS devices includes the group 210-1 of MEMS devices, of which MEMS device 210-1a is an example. The group 210-1 of MEMS devices includes the top row of MEMS devices of the plurality 210 of MEMS devices. The plurality 210 of MEMS devices also includes the plurality 230 of cavities, which are configured to allow motion of movable portions of the plurality 210 of MEMS devices. Similarly, the plurality 230 of cavities includes the group 230-1 of cavities, of which cavity 230-1a is an example. In like fashion, the group 230-1 of cavities includes the top row of cavities of the plurality 230 of cavities. The plurality 210 of MEMS devices and the plurality 230 of cavities are also laid out in orderly arrays of rows and columns such that each MEMS device includes a cavity configured to allow motion of a movable portion of a respective MEMS device. For example, as shown in FIG. 2D, MEMS device 210-1a includes cavity 230-1a. Line 4B-4B indicates the location of a cross-section through the MEMS wafer 201, which is useful for describing the configuration of a movable portion within the MEMS device 210-1a with respect to the cavity 230-1a in the second wafer 201-2, M-wafer, of the MEMS wafer 201, which is subsequently described in discussion of FIG. 4B.

With reference now to FIG. 2E, in accordance with examples of the present technology, another plan view 200E is shown of the first side 201-2a, which is the front side, of the MEMS wafer 201 that includes the E-wafer, which is first wafer 201-1, and the M-wafer, which is second wafer 201-2, of FIGS. 2A and 2B, respectively. The triad of vectors 190, 192 and 194 indicates the orientation of plan view 200E relative to the plan views 100A-200D of FIGS. 1A-2D. FIG. 2E shows an arrangement of the plurality 222 of through holes in the MEMS wafer 201, after removing a plurality of block portions from the second wafer 201-2, M-wafer, overlaying the plurality 220 of electrical contacts of the first wafer 201-1, E-wafer. Similar to FIGS. 2C and 2D, the plurality 210 of MEMS devices includes the group 210-1 of MEMS devices, of which MEMS device 210-1a is an example. The group 210-1 of MEMS devices includes the top row of MEMS devices of the plurality 210 of MEMS devices. The plurality 210 of MEMS devices also includes the plurality 222 of through holes, which are configured to allow access to the plurality 220 of electrical contacts within the plurality 210 of MEMS devices. Similarly, the plurality 222 of through holes includes a group 222-1 of through holes, of which through hole 222-1a is an example. In like fashion, the group 222-1 of through holes includes the top row of through holes of the plurality 222 of through holes. The plurality 210 of MEMS devices and the plurality 222 of through holes are also laid out in orderly arrays of rows and columns such that each MEMS device includes a through hole configured to allow wafer-level testing of the group 210-1 of MEMS devices through the group 222-1 of through holes. For example, MEMS device 210-1a includes through hole 222-1a through which electrical contacts 220-1a of MEMS device 210-1a may be probed for wafer-level testing and screening. FIG. 2E also shows the arrangement of the plurality 230 of cavities in the MEMS wafer 201, after etching the plurality 230 of cavities in the second wafer 201-2 of the MEMS wafer 201, as previously described in the discussion of FIG. 2D. Line 4C-4C indicates the location of a cross-section through the MEMS wafer 201, which is useful for describing the configuration of the through hole 222-1a of the second wafer 201-2, M-wafer, within MEMS device 210-1a with respect to the electrical contacts 220-1a of the first wafer 201-1, E-wafer, of the MEMS wafer 201, which is subsequently described in discussion of FIG. 4C. After removal of the plurality of block portions of the second wafer 201-2, M-wafer, from the MEMS wafer 201 that overlay the plurality 220 of electrical contacts of the first wafer 201-1, E-wafer, and after etching the plurality 230 of cavities in the second wafer 201-2, M-wafer, the MEMS wafer 201 is configured for bonding with the structured glass wafer 101, C-wafer, to cover the MEMS wafer 201 to produce a packaged MEMS wafer 301, as is next described.

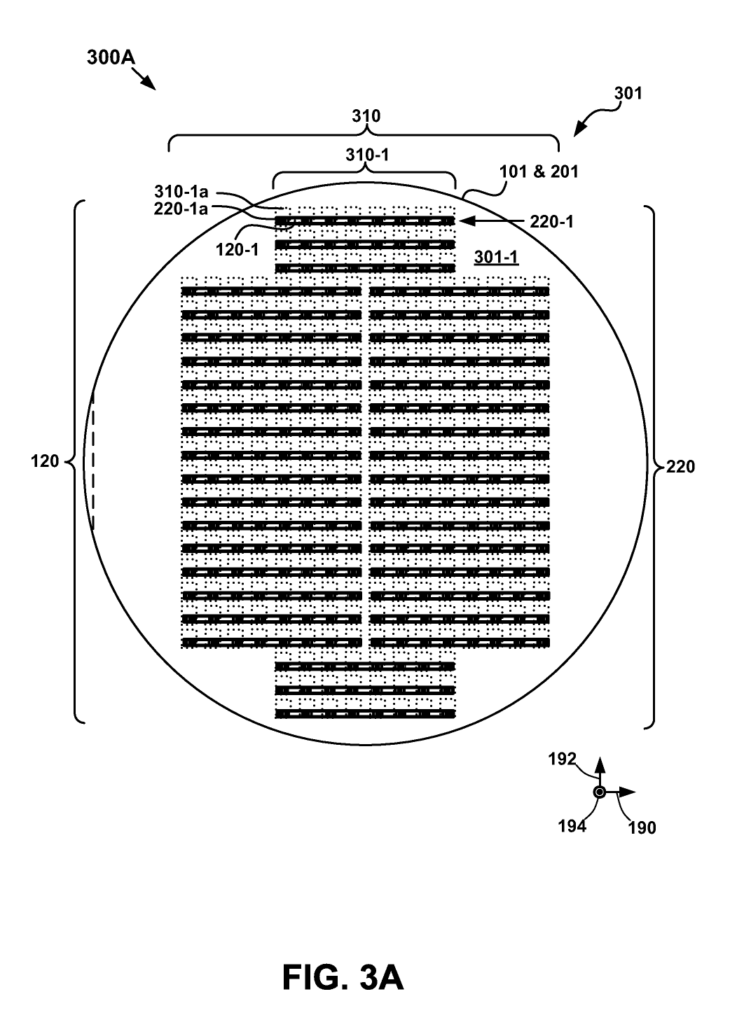

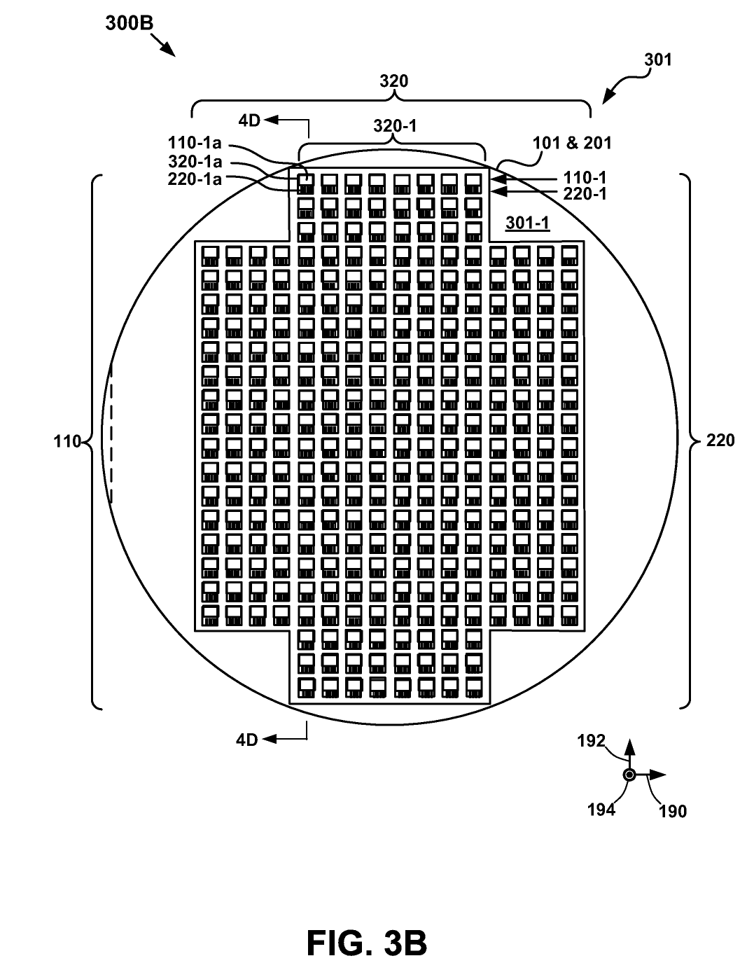

With reference now to FIG. 3A, in accordance with examples of the present technology, a plan view 300A is shown of a first side 301-1, which is the front side, of a packaged MEMS wafer 301. The packaged MEMS wafer 301 includes the structured glass wafer 101, C-wafer, and the MEMS wafer 201. The structured glass wafer 101 is bonded to the MEMS wafer 201. By way of example, a second side 105-2, the back side, of the structured glass wafer 101 may be anodically bonded to the first side 201-2a, the front side, of the second wafer 201-2 of the MEMS wafer 201, without limitation thereto. The MEMS wafer 201 includes the E-wafer, which is the first wafer 201-1, and the M-wafer, which is the second wafer 201-2, previously described in the discussions of respective FIGS. 2A-2E. The triad of vectors 190, 192 and 194 indicates the orientation of plan view 300A relative to the plan views 100A-200E of FIGS. 1A-2E. FIG. 3A shows an arrangement of the plurality 120 of access holes that is aligned with, and configured to provide access to, the plurality 220 of groups of electrical contacts of the E-wafer with respect to a plurality 310 of groups of packaged MEMS devices. For example, access hole 120-1 in the C-wafer is aligned with the group 220-1, the top row, of electrical contacts of a group 310-1, a top row, of packaged MEMS devices. Thus, in accordance with examples of the present technology, access hole 120-1 in the C-wafer provides access to the group 220-1 of electrical contacts of the group 310-1 of packaged MEMS devices.

With further reference to FIG. 3A and FIGS. 1A-2E, in accordance with examples of the present technology, the structured glass wafer 101 includes a sheet of glass 105, the access hole 120-1, and the plurality 130 of cavities formed in the second side 105-2 of the sheet of glass 105. The sheet of glass 105 has first side 105-1 and second side 105-2 opposite first side 105-1. The access hole 120-1 extends through the structured glass wafer 101 from the first side 105-1 to the second side 105-2. The plurality 130 of cavities is formed in the second side 105-2 such that the cavities are configured to accommodate respective MEMS devices. The MEMS wafer 201 has a plurality 210 of MEMS devices and a group 220-1 of electrical contacts of a group 210-1 of MEMS devices. The MEMS wafer 201 and the structured glass wafer 101 are bonded together such that the structured glass wafer 101 covers the plurality 210 of MEMS devices to provide a plurality 310 of packaged MEMS devices. The access hole 120-1 is aligned with the group 220-1 of electrical contacts of the group 210-1 of MEMS devices to allow access to the electrical contacts.

With further reference to FIG. 3A, in accordance with examples of the present technology, the access hole 120-1 is configured to facilitate probing of the group 220-1 of electrical contacts of the group 210-1 of MEMS devices for wafer-level testing of the group 210-1 of MEMS devices. The access hole 120-1 includes an open street in the sheet of glass 105. The electrical contacts 220-1a of a packaged MEMS device 310-1a are disposed near one side of the packaged MEMS device 310-1a. The access hole 120-1 in the sheet of glass 105 has a width about equal to a lateral dimension of at least one electrical contact. The access hole 120-1 is configured to facilitate probing of the group 220-1 of electrical contacts of the group 210-1 of MEMS devices for wafer-level testing of the group 210-1 of MEMS devices. A coefficient of thermal expansion of glass composing the sheet of glass 105 is about equal to a coefficient of thermal expansion of a material composing a portion of a second wafer 201-2 of a MEMS wafer 201 to which the sheet of glass 105 may be bonded. By matching the coefficient of thermal expansion of the glass to the coefficient of thermal expansion of the material composing the portion of the second wafer 201-2 to which the glass is bonded, thermal stresses developed in fabrication, as well as those developed in use, may be reduced, which may lessen failures due to delamination. The sheet of glass 105 may also include a glass that may be anodically bonded to the material composing the portion of the second wafer 201-2 of the MEMS wafer 201.

With reference now to FIG. 3B, in accordance with examples of the present technology, another plan view 300B is shown of the first side 301-1, the front side, of the packaged MEMS wafer 301 of FIG. 3A. The triad of vectors 190, 192 and 194 indicates the orientation of plan view 300B relative to the plan view 100A-300A of FIGS. 1A-3A. FIG. 3B shows the packaged MEMS wafer 301, including the structured glass wafer 101, C-wafer, and the MEMS wafer 201, after dicing the packaged MEMS wafer 301 into a plurality 320 of discrete packaged MEMS devices. The plurality 320 of discrete packaged MEMS devices includes a group 320-1 of discrete packaged MEMS devices, of which discrete packaged MEMS device 320-1a is an example. The group 320-1 of discrete packaged MEMS devices includes the top row of discrete packaged MEMS devices of the plurality 210 of discrete packaged MEMS devices. FIG. 3B also shows an arrangement of a plurality 110 of covering lids from the C-wafer, which are configured to cover the plurality 320 of groups of discrete packaged MEMS devices. The plurality 110 of covering lids of discrete packaged MEMS devices includes a group 110-1 of covering lids of discrete packaged MEMS devices, of which lid 110-1a is an example. The group 110-1 of covering lids of discrete packaged MEMS devices includes the top row of covering lids of the plurality 320 of discrete packaged MEMS devices. By way of example, FIG. 3B shows open streets separating columns and rows of the plurality 320 of discrete packaged MEMS devices, as for a wafer-dicing process such as sawing, or alternatively etching, without limitation thereto. However, embodiments of the present technology also include within their spirit and scope wafer-dicing processes such as scribing-and-breaking, which may be more suitable for a finished wafer having a glass cover wafer, such as the packaged MEMS wafer 301. FIG. 3B also shows the plurality 220 of electrical contacts of the E-wafer with respect to the plurality 320 of discrete packaged MEMS devices. The plurality 220 of electrical contacts of discrete packaged MEMS devices includes the group 220-1 of electrical contacts of discrete packaged MEMS devices, of which electrical contacts 220-1a are an example. The group 220-1 of electrical contacts of discrete packaged MEMS devices includes the top row of electrical contacts of the plurality 320 of discrete packaged MEMS devices. Line 4D-4D indicates the location of a cross-section through the packaged MEMS wafer 301, which is useful for describing the configuration of the lid 110-1a from the structured glass wafer 101, C-wafer, within discrete packaged MEMS device 320-1a, and the configuration of the access hole 120-1 of the structured glass wafer 101 and the through hole 222-1a of the second wafer 201-2, M-wafer, within discrete packaged MEMS device 320-1a with respect to the electrical contacts 220-1a of the first wafer 201-1, E-wafer, of the packaged MEMS wafer 301, which is subsequently described in discussion of FIG. 4D.

With reference now to FIG. 4A, in accordance with examples of the present technology, a cross-sectional elevation view 400A is shown of a MEMS device 210-1a of FIG. 2C along the line 4A-4A of FIG. 2C. The triad of vectors 190, 192 and 194 indicates the orientation of cross-sectional elevation view 400A relative to the plan view 200C of FIG. 2C. The MEMS wafer 201, including the MEMS device 210-1a, is fabricated with silicon on insulator (SOI) technology, the details of which are further described in PCT Patent Application, Serial Number PCT/US2007/081734 by Sriram Ramamoorthi, et al., filed on Oct. 18, 2007, entitled “MICRO ELECTRO MECHANICAL SYSTEM.” As shown in cross-section in FIG. 4A, the first wafer 201-1, E-wafer, of the MEMS wafer 201 includes a silicon substrate 201-1c, a silicon oxide layer 201-1d, and a patterned layer 201-1e. The patterned layer 201-1e includes most of the active electrical components of the first wafer 201-1, the electrical wafer. By way of example, the patterned layer 201-1e includes: a plurality of standoffs, of which standoff 201-11 is an example; a plurality 220 electrical bonding pads, of which electrical bonding pad 220-1a-1 is an example; a plurality of first bond-ring portions, of which first bond-ring portions 201-16a and 201-16b are examples; a plurality of stator-electrode structures, of which stator electrode structure 201-13 is an example; and, a plurality of first interconnect pads, of which first interconnect pad 201-17 is an example. The silicon oxide layer 210-1d may also include lead structures (not shown).

With further reference to FIG. 4A, in accordance with examples of the present technology, the second wafer 201-2, M-wafer, of the MEMS wafer 201 includes a silicon substrate 201-2c, a first silicon oxide layer 201-2d, a silicon layer 201-2e, a second silicon oxide layer 201-2f, and a patterned layer 201-2g. A release layer, R-layer, includes the silicon substrate 201-2c and a substantial portion of the first silicon oxide layer 201-2d. A flexure layer, F-layer, includes the remainder of the first silicon oxide layer 201-2d, the second silicon oxide layer 201-2f, and the patterned layer 201-2g. The patterned layer 201-2g includes most of the active electrical components of the second wafer 201-2. By way of example, the patterned layer 201-2g includes: a plurality of second bond-ring portions, of which second bond-ring portions 201-26a and 201-26b are examples; a plurality of movable-portion electrode structures, of which movable-portion electrode structure 201-23a is an example; and, a plurality of second interconnect pads, of which second interconnect pad 201-27 is an example. The second wafer 201-2, M-wafer, of the MEMS wafer 201 also includes: a plurality of first trenches, of which first trench 201-22a is an example; a plurality of block portions, of which block portion 201-21 is an example; a plurality of movable portions, of which movable portion 201-23 is an example; and, a plurality of flexure suspensions, of which flexure suspension 201-25 is an example. The movable portion 201-23 of the second wafer 201-2, mechanical wafer, includes a proof mass 201-23b and the movable-portion electrode structure 201-23a. FIG. 4A shows the MEMS device 210-1a after first trenches, of which first trench 201-22a is an example, are etched on a second side 201-2b, which is the back side, of the M-wafer.

With further reference to FIG. 4A, in accordance with examples of the present technology, the MEMS wafer 201 includes both the first wafer 201-1, E-wafer, and the second wafer 201-2, M-wafer. The first side 201-1a, the front side, of the first wafer 201-1, E-wafer, is aligned with the second side 201-2b, the back side, of the second wafer 201-2, M-wafer, for bonding with one another to produce the MEMS wafer 201, as indicated by the dashed vertical arrows in FIG. 4A. The first wafer 201-1, E-wafer, has a plurality of electrical components of the respective MEMS devices of the MEMS wafer 201. The second wafer 201-2, M-wafer, has a plurality of movable portions of respective MEMS devices of the MEMS wafer 201. As shown towards the bottom of FIG. 4A, the first wafer 201-1 is joined to the second wafer 201-2 such that the first bond-ring portions 201-16a and 201-16b fuse with respective second bond-ring portions 201-26a and 201-26b, and the first interconnect pad 201-17 fuses with the second interconnect pad 201-27. Standoffs such as standoff 201-11 separate the first wafer 201-1, the electrical wafer, from movable portions, for example, the movable portion 201-23, of the second wafer 201-2, the mechanical wafer. The MEMS wafer 201 also includes a plurality of block portions, of which block portion 201-21 is an example, which are disposed over the plurality 220 of electrical contacts. Operations for the removal of the plurality of block portions are next described.

With reference now to FIG. 4B, in accordance with examples of the present technology, another cross-sectional elevation view 400B is shown of the MEMS device 210-1a of FIG. 2D along the line 4B-4B of FIG. 2D. The triad of vectors 190, 192 and 194 indicates the orientation of cross-sectional elevation view 400B relative to the plan view 200D of FIG. 2D. FIG. 4B shows the MEMS device 210-1a of the MEMS wafer 201 after second trenches, of which second trench 201-22b is an example, are etched on the first side 201-2a, which is the front side, of the second wafer 201-2, the M-wafer. The second trenches, of which second trench 201-22b is an example, are aligned about opposite the first trenches, of which first trench 201-22a is an example, in the second side 201-2b of the second wafer 201-2. The second trenches are joined to the first trenches to form continuous cavities separating the plurality of block portions that overlay the plurality 220 electrical contacts for the first wafer 201-1, the E-wafer. For example, as shown in FIG. 4B, the first trench 201-22a is joined with the second trench 201-22b to form a continuous cavity 201-22 that extends from the first side 201-2a of the second wafer 201-2 to the second side 201-2b of the second wafer 201-2 separating the block portion 201-21 on its right-hand side from the second wafer 201-2. Such trenches are fabricated in the second wafer 201-2 so that a continuous cavity extends completely around block portions, such as block portion 201-21, so that the block portions may be liberated from the second wafer 201-2. FIG. 4B also shows the MEMS device 210-1a after the plurality 230 of cavities, of which cavity 230-1a is an example, are produced in the M-wafer, which is the second wafer 201-2, to allow motion of movable portions, for example, movable portion 201-23, within the plurality 210 of MEMS devices, of which MEMS device 210-1a is an example. Both the plurality 230 of cavities, of which cavity 230-1a is an example, and the plurality of second trenches, of which second trench 201-22b is an example, may be produced by an etching process such as, for example, reactive-ion etching (RIE).

With reference now to FIG. 4C, in accordance with examples of the present technology, another cross-sectional elevation view 400C is shown of the MEMS device 210-1a of FIG. 2E along the line 4C-4C of FIG. 2E. The triad of vectors 190, 192 and 194 indicates the orientation of cross-sectional elevation view 400C relative to the plan view 200E of FIG. 4E. FIG. 4C shows the MEMS device 210-1a after the plurality of block portions, of which block portion 201-21 is an example, are removed. After the plurality of block portions, of which block portion 201-21 is an example, are removed from the MEMS wafer 201, the plurality 222 of through holes in the second wafer 201-2, the M-wafer, are produced, which allows access to the plurality 220 electrical bonding pads, of which electrical bonding pad 220-1a-1 is an example. FIG. 4C also shows the electrical bonding pad 220-1a-1 on the E-wafer, which is the first wafer 201-1, exposed for wafer-level testing of the MEMS device 210-1a of the MEMS wafer 201.

With reference now to FIG. 4D, in accordance with examples of the present technology, another cross-sectional elevation view 400D is shown of a discrete packaged MEMS device 320-1a of FIG. 3B along the line 4D-4D of FIG. 3B. The triad of vectors 190, 192 and 194 indicates the orientation of cross-sectional elevation view 400D relative to the plan view 300B of FIG. 3B. FIG. 4D shows the discrete packaged MEMS device 320-1a after bonding the structured glass wafer 101 of FIG. 1C to the MEMS wafer 201 of FIG. 2E to provide a packaged MEMS wafer 301. FIG. 4D also shows the discrete packaged MEMS device 320-1a after dicing the packaged MEMS wafer 301 of FIG. 3A to produce a plurality 320 of discrete packaged MEMS devices, of which discrete packaged MEMS device 320-1a is an example. After dicing the packaged MEMS wafer 301, the plurality 210 of MEMS devices are provided with a plurality 110 of lids fabricated from the structured glass wafer 101. In addition, the plurality 130 of cavities on the second side 105-2, the back side, of the structured glass wafer 101 are aligned with the plurality 230 of cavities on the first side 201-2a of the MEMS wafer 201 so that the plurality of movable portions of the second wafer 201-2, the mechanical wafer, are accommodated by the structured glass wafer 101. For example, as shown in FIG. 4D, the lid 110-1a covers the cavity 230-1a accommodating the movable portion 201-23 with the cavity 130-1a of the structured glass wafer 101. Also shown in FIG. 4D, is the access hole 120-1 aligned with the through hole 222-1a and the electrical bonding pad 220-1a-1 after removal of the block portion 201-21 from the second wafer 201-2, the mechanical wafer.

With reference now to FIG. 4E, in accordance with examples of the present technology, another cross-sectional elevation view 400E is shown of an alternative example discrete packaged MEMS device 420-1a similar to that of FIG. 3B. The triad of vectors 190, 192 and 194 indicates the orientation of cross-sectional elevation view 400E relative to the plan view 300B of FIG. 3B. FIG. 4E shows a discrete packaged MEMS device 420-1a, similar to the discrete packaged MEMS device 320-1a, after bonding an alternative example structured glass wafer 405 similar to that of FIG. 1C, but without cavities on the second side 105-2, to the MEMS wafer 201 of FIG. 2E to provide an alternative example packaged MEMS wafer 401, similar to the packaged MEMS wafer 301. For reference, the first side 401-1, the front side, of the packaged MEMS wafer 401 is indicated in FIG. 4E. FIG. 4E also shows the discrete packaged MEMS device 420-1a, after dicing the packaged MEMS wafer 401 to produce a plurality of discrete packaged MEMS devices. After dicing the packaged MEMS wafer 401, the plurality of MEMS devices are provided with a plurality of lids, of which lid 410-1a is an example, fabricated from the structured glass wafer 405. However, the plurality 130 of cavities on the second side 105-2, the back side, of the structured glass wafer 101 are absent from this alternative example structured glass wafer 405. The space to allow motion of the movable portion 201-23 of the MEMS device is made available by the cavity 230-1a, which is a result of M-wafer etching. Also shown in FIG. 4E, is the access hole 120-1 aligned with the through hole 222-1a and the electrical bonding pad 220-1a-1 after removal of the block portion 201-21 from the second wafer 201-2, the mechanical wafer.

With reference now to FIG. 4F, in accordance with examples of the present technology, another cross-sectional elevation view 400F is shown of an alternative example discrete packaged MEMS device 425-1a device similar to that of FIG. 3B. The triad of vectors 190, 192 and 194 indicates the orientation of cross-sectional elevation view 400F relative to the plan view 300B of FIG. 3B. FIG. 4F shows the discrete packaged MEMS device 425-1a, similar to the discrete packaged MEMS device 320-1a, after bonding the structured glass wafer 101 of FIG. 1C to the MEMS wafer 201 of FIG. 2E to provide an alternative example packaged MEMS wafer 402 having a movable portion 201-23 further including an additional-mass portion 201-23c. For reference, the first side 402-1, the front side, of the packaged MEMS wafer 402 is indicated in FIG. 4F. In the alternative example of the present technology shown in FIG. 4F, the space to allow motion of the movable portion 201-23 of the discrete packaged MEMS device 425-1a is primarily made available by cavity 130-1a on the C-wafer, the structured glass wafer 101. Etching the first side 201-2a, front side, of the M-wafer, allows the release of the movable portion 201-23 of the discrete packaged MEMS device 425-1a. Also, in etching the first side 201-2a, front side, of the M-wafer, only part of the material is removed from the silicon substrate 201-2c to form the cavity 230-1a, and the majority of the silicon substrate 201-2c is kept to provide increased mass for the movable portion 201-23, which is shown as an additional-mass portion 201-23c of the movable portion 201-23. The additional-mass portion 201-23c of the movable portion 201-23 provides added mass to the movable portion 201-23 that lowers thermal mechanical noise without reducing cavity pressure. This alternative example of the present technology creates an ultra-low noise sensor for seismic applications, which is a motivating factor for developing such technology.

With further reference to FIG. 4F, in accordance with examples of the present technology, the discrete packaged MEMS device 425-1a is shown after dicing the packaged MEMS wafer 402 to produce a plurality of discrete packaged MEMS devices, of which discrete packaged MEMS device 425-1a is an example. After dicing the packaged MEMS wafer 402, the plurality of MEMS devices are provided with a plurality 110 of lids, of which lid 110-1a is an example, fabricated from the structured glass wafer 101. In addition, the plurality 130 of cavities on the second side 105-2, the back side, of the structured glass wafer 101 are aligned with the plurality 230 of cavities on the first side 201-2a of the MEMS wafer 201 so that the plurality of movable portions of the second wafer 201-2, the mechanical wafer, are accommodated by the structured glass wafer 101. For example, as shown in FIG. 4F, the lid 110-1a covers the cavity 230-1a accommodating the movable portion 201-23 with the cavity 130-1a of the structured glass wafer 101. Also shown in FIG. 4F, is the access hole 120-1 aligned with the through hole 222-1a and the electrical bonding pad 220-1a-1 after removal of the block portion 201-21 from the second wafer 201-2, the mechanical wafer.

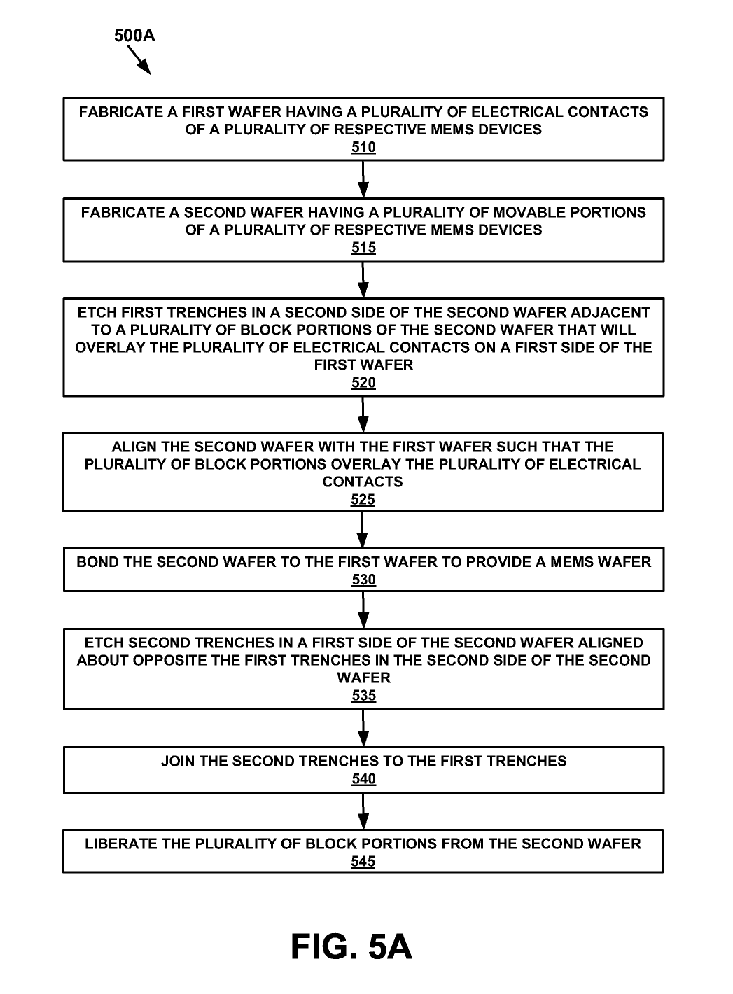

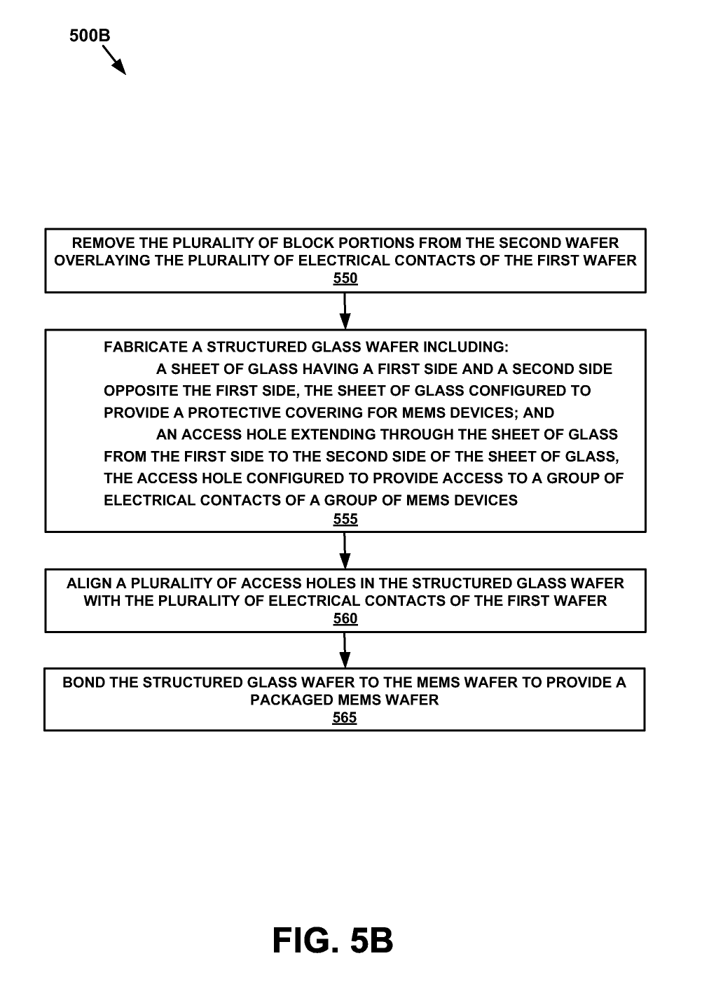

With reference now to FIG. 5A, in accordance with examples of the present technology, a flowchart 500A is shown of a method for fabricating a packaged MEMS wafer. The method for fabricating the packaged MEMS wafer includes the following operations. At 510 a first wafer, which is the E-wafer, which has a plurality of electrical contacts of a plurality of respective MEMS devices, is fabricated. At 515 a second wafer, which is the M-wafer, which has a plurality of movable portions of a plurality of respective of MEMS devices, is fabricated. At 520 first trenches are etched in a second side of the second wafer adjacent to a plurality of block portions of the second wafer that will overlay the plurality of electrical contacts on a first side of the first wafer. At 525 the second wafer is aligned with the first wafer such that the plurality of block portions overlay the plurality of electrical contacts. At 530 the second wafer is bonded to the first wafer to provide a MEMS wafer. At 535 second trenches are etched in a first side of the second wafer aligned about opposite the first trenches in the second side of the second wafer. At 540 the second trenches are joined to the first trenches. At 545 the plurality of block portions is liberated from the second wafer.

With reference now to FIG. 5B, in accordance with examples of the present technology, a flowchart 500B is shown of further operations that may be employed in the method for fabricating a packaged MEMS wafer. The method for fabricating a packaged MEMS wafer may further include the following operations. At 550 the plurality of block portions overlaying the plurality of electrical contacts of the first wafer is removed from the second wafer. At 555 a structured glass wafer, which is the C-wafer, is fabricated. As previously described, the structured glass wafer includes a sheet of glass, and an access hole. The sheet of glass has a first side and a second side opposite the first side, and is configured to provide a protective covering for MEMS devices. The access hole extends through the sheet of glass from the first side to the second side of the sheet of glass, and is configured to provide access to a group of electrical contacts of a group of MEMS devices. The structured glass wafer may also include a plurality of cavities. The plurality of cavities is formed in the second side of the sheet of glass, do not extend completely through the sheet of glass, and is configured to accommodate respective MEMS devices.

With further reference to FIG. 5B, at 560, in accordance with examples of the present technology, a plurality of access holes in the structured glass wafer is aligned with the plurality of electrical contacts of the first wafer. At 565 the structured glass wafer is bonded to the MEMS wafer to provide a packaged MEMS wafer. The method may also further include the following operations: probing of the plurality of electrical contacts of the plurality of MEMS devices for wafer-level testing of the plurality of MEMS devices; and, dicing the packaged MEMS wafer into a plurality of discrete packaged MEMS devices.

The foregoing descriptions of specific examples of the present technology have been presented for purposes of illustration and description. They are not intended to be exhaustive or to limit the technology to the precise forms disclosed, and many modifications and variations are possible in light of the above teaching. For example, in one example of the present technology, getter material may be added to the cavity in which the movable portion is disposed. The getter material may be provided by depositing a thin film of getter material onto the back side of the structured glass wafer and/or the front side of the MEMS wafer prior to bonding the two together to form the packaged MEMS wafer. Adding getter material allows the cavity pressure to be reduced and an even lower noise floor may be achieved for a MEMS device that is an ultra-low noise sensor for seismic applications. The examples described herein were chosen and described in order to best explain the principles of the technology and its practical application, to thereby enable others skilled in the art to best utilize the technology and various examples with various modifications as are suited to the particular use contemplated. It may be intended that the scope of the technology be defined by the claims appended hereto and their equivalents.

What is claimed is:

1. A structured glass wafer for packaging a microelectromechanical-system (MEMS) wafer, said structured glass wafer comprising:
a sheet of glass having a first side and a second side opposite said first side, said sheet of glass configured to provide a protective covering for MEMS devices; and
an access hole extending through said sheet of glass from said first side to said second side of said sheet of glass, said access hole configured to provide access to a group of electrical contacts of a group of MEMS devices.

2. The structured glass wafer of claim 1, further comprising:
a plurality of cavities formed in said second side of said sheet of glass, said cavities not extending completely through said sheet of glass, said cavities configured to accommodate respective MEMS devices.

3. The structured glass wafer of claim 1, wherein said access hole and a plurality of cavities are prefabricated in said sheet of glass prior to bonding said structured glass wafer to a MEMS wafer.

4. The structured glass wafer of claim 3, wherein said plurality of access holes comprises a plurality of open streets in said sheet of glass.

5. The structured glass wafer of claim 1, wherein said access hole is configured to facilitate probing of said group of electrical contacts of said group of MEMS devices for wafer-level testing of said group of MEMS devices.

6. The structured glass wafer of claim 1, wherein a coefficient of thermal expansion of glass composing said sheet of glass is about equal to a coefficient of thermal expansion of a material composing a portion of a second wafer of a MEMS wafer to which said sheet of glass may be bonded.

7. The structured glass wafer of claim 1, wherein said sheet of glass comprises glass that may be anodically bonded to a material composing a portion of a second wafer of a MEMS wafer to which said sheet of glass may be bonded.

8. The structured glass wafer of claim 1, wherein said sheet of glass has about a circular shape.

9. The structured glass wafer of claim 8, wherein said sheet of glass has a diameter of greater than or equal to about 20 millimeters (mm).

10. A packaged MEMS wafer comprising:
a structured glass wafer comprising:
a sheet of glass having a first side and a second side opposite said first side; and
an access hole extending through said structured glass wafer from said first side to said second side; and
a MEMS wafer having a plurality of MEMS devices and a group of electrical contacts of a group of MEMS devices, said MEMS wafer and said structured glass wafer bonded together such that said structured glass wafer covers said plurality of MEMS devices and said access hole is aligned with said group of electrical contacts of said group of MEMS devices to allow access to said group of electrical contacts of said group of MEMS devices.

11. The packaged MEMS wafer of claim 10, wherein said structured glass wafer further comprises a plurality of cavities formed in said second side, said cavities not extending completely through said sheet of glass, said cavities configured to accommodate respective MEMS devices.

12. The packaged MEMS wafer of claim 10, wherein said access hole is configured to facilitate probing of said group of electrical contacts of said group of MEMS devices for wafer-level testing of said group of MEMS devices.

13. The packaged MEMS wafer of claim 10, wherein electrical contacts of a MEMS device are disposed near one side of said MEMS device.

14. The packaged MEMS wafer of claim 10, wherein said MEMS wafer comprises:
a first wafer having a plurality of electrical components of said respective MEMS devices; and
a second wafer having a plurality of movable portions of respective MEMS devices.

15. The packaged MEMS wafer of claim 14, wherein said second wafer comprises:
a group of through holes in said second wafer so that said group of electrical contacts of said first wafer is exposed for wafer-level testing of said group of MEMS devices.

16. The packaged MEMS wafer of claim 10, wherein said structured glass wafer is anodically bonded to said second wafer.

17. A method for fabricating a packaged MEMS wafer comprising:
fabricating a first wafer having a plurality of electrical contacts of a plurality of respective MEMS devices;
fabricating a second wafer having a plurality of movable portions of a plurality of respective MEMS devices;
etching first trenches in a second side of said second wafer adjacent to a plurality of block portions of said second wafer that will overlay said plurality of electrical contacts on a first side of said first wafer;
aligning said second wafer with said first wafer such that said plurality of block portions overlay said plurality of electrical contacts;
bonding said second wafer and said first wafer to provide a MEMS wafer;
etching second trenches in a first side of said second wafer aligned about opposite said first trenches in said second side of said second wafer;
joining said second trenches to said first trenches; and
liberating said plurality of block portions from said second wafer.

18. The method of claim 17, further comprising:
removing said plurality of block portions from said second wafer overlaying said plurality of electrical contacts of said first wafer;
fabricating a structured glass wafer comprising:
a sheet of glass having a first side and a second side opposite said first side, said sheet of glass configured to provide a protective covering for MEMS devices; and
an access hole extending through said sheet of glass from said first side to said second side of said sheet of glass, said access hole configured to provide access to a group of electrical contacts of a group of MEMS devices;
aligning a plurality of access holes in said structured glass wafer with said plurality of electrical contacts of said first wafer;
bonding said structured glass wafer to said MEMS wafer to provide a packaged MEMS wafer.

19. The method of claim 18, further comprising:
probing of said plurality of electrical contacts of said plurality of MEMS devices for wafer-level testing of said plurality of MEMS devices; and
dicing said packaged MEMS wafer into a plurality of discrete packaged MEMS devices.

20. The method of claim 17, further comprising:
removing said plurality of block portions from said second wafer overlaying said plurality of electrical contacts of said first wafer;
fabricating a structured glass wafer comprising:
a sheet of glass having a first side and a second side opposite said first side, said sheet of glass configured to provide a protective covering for MEMS devices;
an access hole extending through said sheet of glass from said first side to said second side of said sheet of glass, said access hole configured to provide access to a group of electrical contacts of a group of MEMS devices; and
a plurality of cavities formed in said second side of said sheet of glass, said cavities not extending completely through said sheet of glass, said cavities configured to accommodate said MEMS devices;
aligning a plurality of access holes in said structured glass wafer with said plurality of electrical contacts of said first wafer;
bonding said structured glass wafer to said MEMS wafer to provide a packaged MEMS wafer.
